(19) United States
(12) Patent Application Publication
(10) Pub. No.: US 2011/0227538 A1
(43) Pub. Date: Sep. 22, 2011

(54) CIRCUITS FOR GENERATING REFERENCE SIGNALS

(75) Inventor: Guoxing LI, Sunnyvale, CA (US)

(73) Assignee: O2MICRO, INC, Santa Clara, CA (US)

(21) Appl. No.: 13/039,751

(22) Filed: Mar. 3, 2011

Related U.S. Application Data
(60) Provisional application No. 61/315,486, filed on Mar. 19, 2010.

(51) Int. Cl. H02J 7/00; H03H 1/00

(52) U.S. Cl. 320/134; 323/364; 320/128; 320/162; 320/136

(57) ABSTRACT

A circuit for generating a reference signal can include a first resistor string and a second resistor string substantially identical to the first resistor string, a trim circuit, and a resistor controller. The trim circuit coupled to the first resistor string is operable for generating the reference signal according to a terminal voltage at a terminal in the first resistor string. The resistor controller coupled to the first resistor string and the second resistor string is operable for selectively shorting out a resistor in the first resistor string and a corresponding resistor in the second resistor string.

### RELATED APPLICATION

This application claims priority to U.S. Provisional Application No. 61/315,486, titled “Reference Circuit for Generating Adjustable Signals”, filed on Mar. 19, 2010, which is hereby incorporated by reference in its entirety.

### BACKGROUND ART

Reference circuits generating reference voltages are used in various semiconductor applications. FIG. 1 shows a reference circuit 100 in prior art. The reference circuit 100 includes an error amplifier 110, a trim controller 120, and a resistor string 150. The resistor string 150 may include resistors 130, 140, 152 and 154. The error amplifier 110 compares the bandgap reference voltage V_{BG} with a signal from the trim controller 120, and generates a reference voltage V_{OUT}. Since the bandgap reference voltage V_{BG} may vary, the trim controller 120 is used to improve the accuracy of the reference voltage V_{OUT} by compensating the variation in the bandgap reference voltage V_{BG} in order to generate the reference voltage V_{OUT} at a desired level or range. More specifically, the trim controller 120 can selectively short out one or more resistors in the resistor string 150 and can selectively pass a voltage at a terminal (e.g., node 153) in the resistor string 150 to the error amplifier 110 in order to generate the reference voltage V_{OUT} at a desired level or range.

In some applications such as battery management systems, multiple reference signals may be needed or desired. To generate different reference signals, each reference signal is generated by a corresponding reference circuit 100 in some conventional methods, which includes a corresponding error amplifier, a trim controller and a resistor string, thereby increasing the die size, power consumption, and the complexity in trimming circuits.

### BRIEF DESCRIPTION OF THE DRAWINGS

The accompanying drawings, which are incorporated in and form a part of this specification, illustrate embodiments of the present invention and, together with the description, serve to explain the principles of the invention:

FIG. 1 shows a reference circuit in prior art.

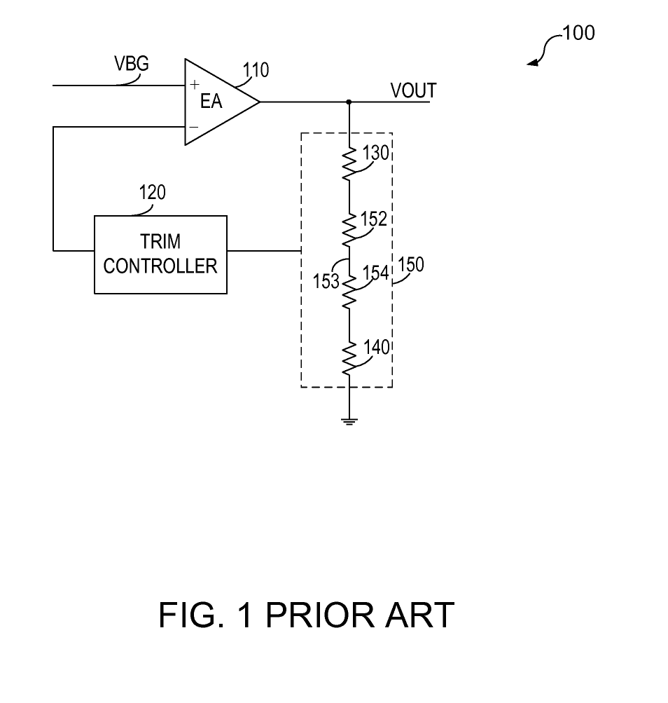

FIG. 2 illustrates a block diagram of a reference circuit for generating reference signals, in accordance with one embodiment of the present invention.

FIG. 3 shows a block diagram of a battery management system for controlling charging/discharging of a battery pack, in accordance with one embodiment of the present invention.

FIG. 4 shows a schematic diagram of a reference circuit for generating reference signals, in accordance with one embodiment of the present invention.

FIG. 5 shows a flowchart of a method for generating a reference signal, in accordance with one embodiment of the present invention.

### SUMMARY

In one embodiment, a circuit for generating a reference signal includes a first resistor string and a second resistor string substantially identical to the first resistor string, a trim circuit, and a resistor controller. The trim circuit coupled to the first resistor string is operable for generating the reference signal according to a terminal voltage at a terminal in the first resistor string. The resistor controller coupled to the first resistor string and the second resistor string is operable for selectively shorting out a resistor in the first resistor string and a corresponding resistor in the second resistor string.

### DETAILED DESCRIPTION

Reference will now be made in detail to the embodiments of the present invention, examples of which are illustrated in the accompanying drawings. While the invention will be described in conjunction with the embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of embodiments of the present invention, numerous specific details are set forth in order to provide a thorough understanding of the present invention. However, it will be recognized by one of ordinary skill in the art that the present invention may be practiced without these specific details. In other instances, well-known methods, procedures, components, and circuits have not been described in detail as not to unnecessarily obscure aspects of the embodiments of the present invention.

Embodiments in accordance with the present invention provide reference circuits that generate reference signals with improved accuracy, while having smaller die size, lower power consumption, and less complex circuit structure.

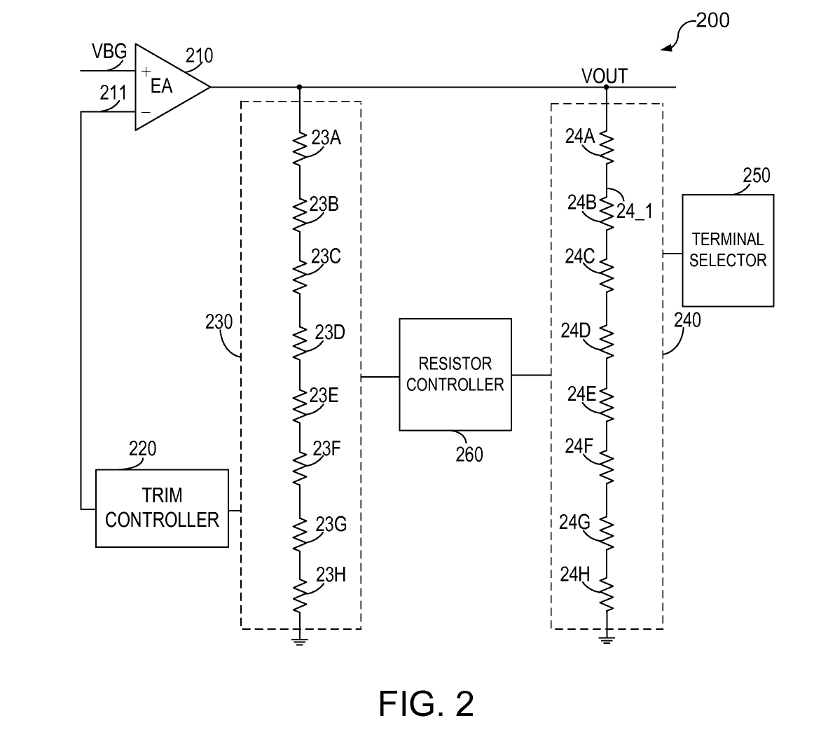

FIG. 2 illustrates a block diagram of a reference circuit 200 for generating reference signals, in accordance with one embodiment of the present invention. In the example of FIG. 2, the circuit 200 generates reference signals based on a bandgap reference voltage V_{BG}. In one embodiment, the circuit 200 includes a trim circuit (including an error amplifier 210 and a trim controller 220), a terminal selector 250, a resistor controller 260, and resistor strings 230 and 240.

In one embodiment, the resistor strings 230 and 240 are substantially identical. In the example of FIG. 2, the first resistor string 230 includes resistors 23A-23H and the second resistor string 240 includes resistors 24A-24H for illustration purposes but not limitation.

The trim controller 220 is coupled to the first resistor string 230 and operable for selectively passing a terminal voltage at a terminal in the first resistor string 230 to the error amplifier 210. In one embodiment, the trim controller 220 includes a multiplexer for selectively passing a terminal voltage at a terminal in the first resistor string 230 to the error amplifier 210. The error amplifier 210 compares the received terminal voltage 211 with the bandgap voltage V_{BG} to generate the reference voltage V_{OUT}. In one embodiment, the reference voltage V_{OUT} is proportional to the bandgap voltage V_{BG}.

The resistor controller 260 coupled to the resistor strings 230 and 240 can short out corresponding resistors in the resistor strings 230 and 240. In one embodiment, resistor strings 230 and 240 are substantially identical, and the resistor controller 260 selectively shorts out one or more resistors in the resistor string 230 and corresponding resistor(s) in the resistor string 240. For example, the resistor controller 260 shorts out the resistor 23D in the resistor string 230 and the resistor 24D in the resistor string 240.

The terminal selector 250 can select one or more terminals in the resistor string 240 and output the voltages at the selected terminals as additional reference voltages. For example, the terminal selector 250 can output the terminal voltage at terminal 24_1 in the example of FIG. 2.

Advantageously, the reference circuit 200 can generate multiple reference signals. By including the resistor string 240 that is substantially identical to the resistor string 230, the design flexibility is enhanced because independent reference signals can be generated, e.g., when adjusting one reference signal, other reference signals are not affected. Moreover, once a reference voltage is trimmed, other reference voltages generated by the circuit 200 are also automatically trimmed without additional trimming procedures. Furthermore, by including a trim controller, an error amplifier and resistor strings, the reference circuit 200 has lower power consumption and smaller die size. In the example of FIG. 2, the reference circuit 200 includes a terminal selector and a resistor controller for illustration purposes but not limitation. The reference circuit 200 can include multiple terminal selectors and resistor controllers.

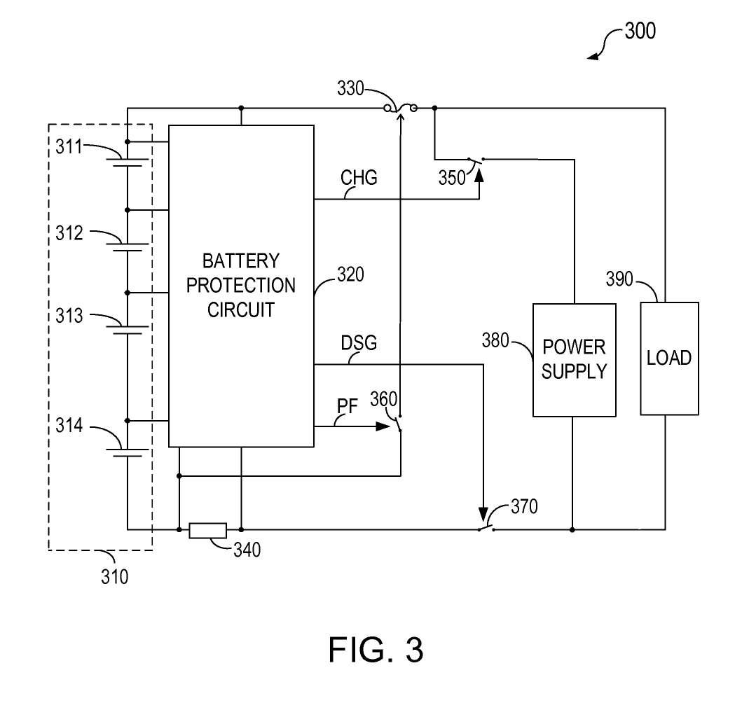

FIG. 3 shows a block diagram of a battery management circuit/system 300 for controlling charging and discharging of a battery pack 310, in accordance with one embodiment of the present invention. The battery pack 310 can be, but is not limited to, a Lithium-Ion battery, a Polymer battery or a Lead-Acid battery. Although the invention is described in relation to a battery, the invention is not so limited. For example, the battery pack 310 can be replaced by solar cells. In the example of FIG. 3, the system 300 further includes circuitry such as a battery protection circuit 320, a fuse 330, a sensor 340, switches 350, 360 and 370, a power supply 380, and a load 390.

In the example of FIG. 3, the battery pack 310 includes battery cells 311-314. The sensor 340, e.g., a resistor, senses the current flowing through the battery pack 310. The battery protection circuit 320 detects the statuses of the cells 311-314, such as cell voltages and a current flowing through the cells, and controls the switches 350, 360 and 370 accordingly to control the charging and discharging of the battery pack 310. Thus, the battery protection circuit 320 protects the battery pack from undesired or abnormal conditions, e.g., over-voltage, over-current, and under-voltage conditions.

By way of example, if a cell voltage is higher than a predetermined over-voltage threshold for a predetermined period of time, the battery protection circuit 320 triggers an over-voltage protection, e.g., terminate charging. The battery protection circuit 320 can turn off the switch 350 through a signal CHG to cut off the charging current flowing from the power supply 380, through the switch 350 and the fuse 330 to the battery pack 310. If the cell voltage drops below a predetermined over-voltage release threshold, the battery protection circuit 320 turns on the switch 350 to release the over-voltage protection. In one embodiment, if a cell voltage is greater than a predetermined over-voltage-permanent-failure threshold which is higher than the over-voltage threshold, the battery protection circuit 320 triggers an over-voltage-permanent-failure protection. The battery protection circuit 320 turns on the switch 360 through a signal PF to short and burn the fuse 330, and the charging is permanently terminated unless a new fuse is replaced.

In one embodiment, if a cell voltage is lower than a predetermined under-voltage threshold for a predetermined period of time, the battery protection circuit 320 triggers an under-voltage protection, e.g., terminate discharging. The battery protection circuit 320 turns off the switch 370 through a signal DSG to cut off the discharging current flowing from the battery pack 310, through the fuse 330, the load 390, the switch 370, and the sensor 340 back to the battery pack 310. If the cell voltage increases above a predetermined under-voltage release threshold, the battery protection circuit 320 turns on the switch 370 to release the under-voltage protection.

In one embodiment, if the charging or discharging current of the battery pack 310 is higher than a predetermined over-current threshold for a predetermined period of time, the battery protection circuit 320 triggers an over-current protection by terminating charging or discharging. For example, during discharging, if the voltage drop on the sensor 340 is higher than the predetermined over-current threshold for a predetermined period of time, the battery protection circuit 320 triggers the over-current protection by turning off the switch 370 to cut off the battery discharging current. During charging, if the voltage drop on the sensor 340 is higher than the predetermined over-current threshold for a predetermined period of time, the battery protection circuit 320 triggers the over-current protection by turning off the switch 330 to cut off the battery charging current.

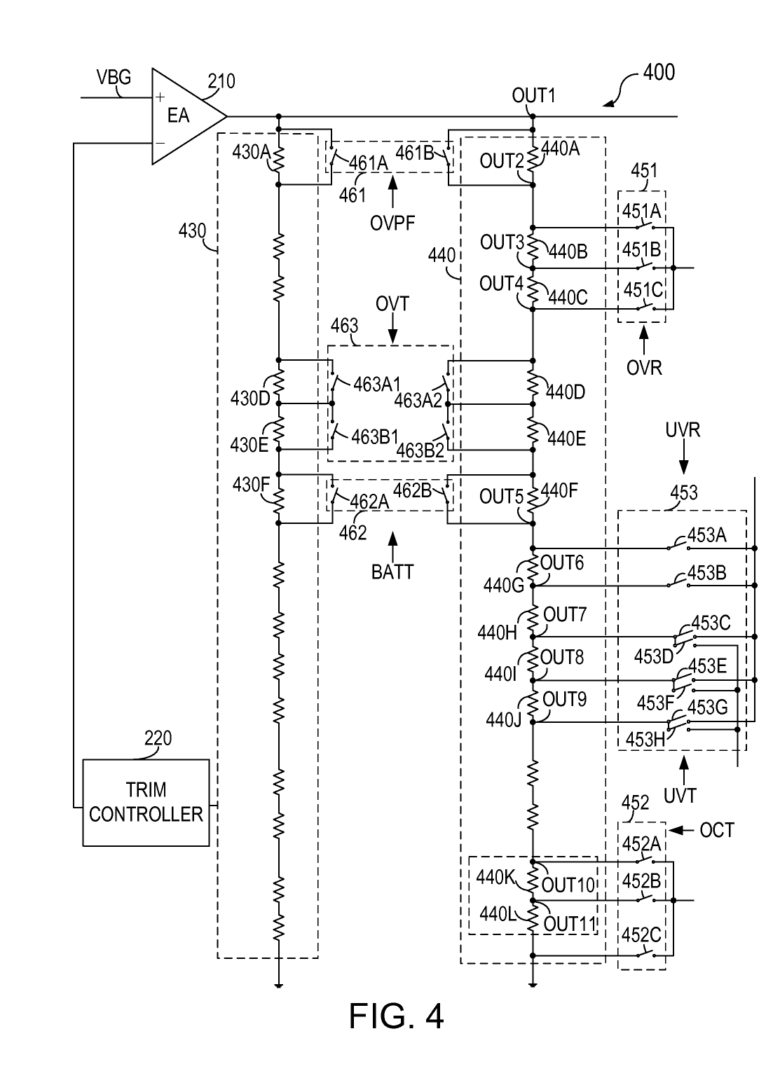

FIG. 4 shows a schematic diagram of a reference circuit 400 for generating reference voltages, in accordance with one embodiment of the present invention. Elements labeled the same in FIG. 2 have similar functions. FIG. 4 is described in combination with FIG. 2 and FIG. 3.

In the example of FIG. 4, the reference circuit 400 includes an error amplifier 210, a trim controller 220, terminal selectors 451-453, resistor controllers 461-463, and resistor strings 430 and 440. The resistor strings 430 and 440 are substantially identical, in one embodiment.

In one embodiment, the reference circuit 400 generates one or more reference voltages such as an over-voltage threshold, an over-voltage release threshold, an over-voltage-permanent-failure threshold, an under voltage threshold, an under-voltage release threshold and an over-current threshold for the battery management system 300 in the example of FIG. 3. Advantageously, the thresholds can be adjusted according to the type of the battery pack and different applications, making the reference circuit 400 flexible for different battery management systems. However, the invention is not limited to battery management systems. The circuit 400 can also be used to generate various references for various other purposes or applications.

In the example of FIG. 4, the resistor controller 461 includes switches 461A and 461B. By turning on the switches 461A and 461B, the resistor controller 461 shorts out the resistors 430A and 440A respectively. In one embodiment, the switches 461A and 461B can be controlled by a signal OVPF indicating whether an over-voltage-permanent-failure protection is desired or needed in a battery protection application. If the over-voltage-permanent-failure protection is desired or needed, the switches 461A and 461B are turned off, and the voltage at the output terminal OUT1 can be output as the over-voltage-permanent-failure threshold and the voltage at the output terminal OUT2 can be output as the over-voltage threshold. Otherwise, the switches 461A and 461B are turned on, and the voltage at the output terminal OUT2 can be output as the over-voltage threshold. The switches described in the present invention can have various types and can be but not limited to N-channel metal-oxide-semiconductor field effect transistors or P-channel metal-oxide-semiconductor field effect transistors.

Similarly, the resistor controller 462 can include switches 462A and 462B for shorting out the resistors 430F and 440F, respectively. In one embodiment, the resistor controller 462 can be controlled by a signal BATT indicating the battery type. For example, for Lithium-Ion batteries or Polymer batteries, the switches 462A and 462B are turned off. For Lead-Acid batteries, the switches 462A and 462B are turned on. By way of example, the over-voltage threshold of a Lithium Ion battery or Polymer battery is 4.0V, and the over-voltage threshold of a Lead Acid battery is 2.4V. Advantageously, under the control of the resistor controller 462, the over-voltage threshold can be adjusted according to different battery types.

In the example of FIG. 4, the resistor controller 463 includes switches 463A1 and 463B1 coupled to the resistors 430D and 430E in parallel respectively, and includes switches 463A2 and 463B2 coupled to resistors 440D and 440E in parallel respectively. According to a signal OVT, the resistor controller 463 can short out one or more resistors in the resistor string 430 and also short out corresponding resistors in the resistor string 440. Advantageously, the voltage at the terminal OUT2 can be further adjusted to different levels according to different system needs. By way of example, the over-voltage threshold for a Lithium Ion battery can be adjusted among eight levels from 4.0V to 4.35V.

In the example of FIG. 4, the terminal selector 451 includes switches 451A-451C coupled to resistors 440B and 440C. The terminal selector 451 can select a terminal voltage from terminals OUT2, OUT3 and OUT4 according to a signal OVR and output the selected terminal voltage. In one embodiment, the terminal voltage selected and output according to the signal OVR can be an over-voltage release threshold. In one embodiment, the over-voltage release threshold is no greater than the over-voltage threshold.

Similarly, the terminal selector 452 includes switches 452A-452C coupled to resistors 440K and 440L for selecting a terminal voltage from terminals OUT10, OUT11 and ground according to a signal OCT and outputting the selected terminal voltage. In one embodiment, the terminal voltage selected and output according to the signal OCT can be an over-current threshold, e.g., 0.25V.

In the example of FIG. 4, the terminal selector 453 includes switches 453A-453H coupled to resistors 440G-440J. According to a signal UVT, the terminal selector 453 can select a terminal voltage from terminals OUT7, OUT8 and OUT9 by controlling the switches 453D, 453F and 453H, and output the selected terminal voltage. In one embodiment, the terminal voltage selected and output according to the signal UVT can be an under-voltage threshold. Moreover, according to a signal UVR, the terminal selector 453 can select a terminal voltage from terminals OUT5-OUT9 by controlling the switches 453A-453C, 453E and 453G, and output the selected terminal voltage. In one embodiment, the terminal voltage selected and output according to the signal UVR can be an under-voltage release threshold. For example, the under-voltage release threshold can be 0-1V higher than the under-voltage threshold.

Advantageously, in one embodiment, by employing the terminal selectors 451-453, the reference circuit 400 can adjust a reference voltage without affecting other reference voltages, for example, the reference circuit 400 can adjust the reference voltage selected and output by the terminal selector 451 without affecting the reference voltage selected and output by the terminal selector 452. By employing the resistor controllers 462-463, the reference circuit 400 can adjust multiple reference voltages simultaneously, for example, the reference circuit 400 can adjust the reference voltages at the terminal OUT1 and OUT2 simultaneously through the resistor controller 463.

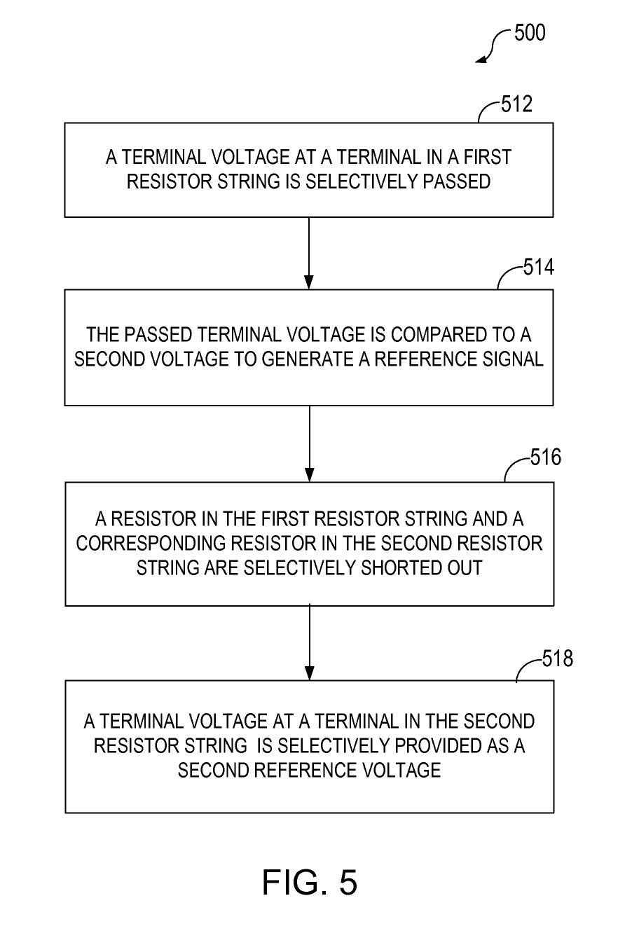

FIG. 5 illustrates a flowchart of a method 500 for generating a reference signal. FIG. 5 is described in combination with FIG. 2. Although specific steps are disclosed in FIG. 5, such steps are examples. That is, the present invention is well suited to perform various other steps or variations of the steps recited in FIG. 5.

At step 512, a terminal voltage at a terminal in a first resistor string is selectively passed. At step 514, the terminal voltage is compared to a second voltage to generate the reference signal. At step 516, a resistor in the first resistor string and a corresponding resistor in a second resistor string which is substantially identical to the first resistor string are selectively shorted out. At step 518, a terminal voltage at a terminal in the second resistor string is selectively provided as a second reference voltage. In one embodiment, charging of a battery is controlled according to the reference signal. In another embodiment, discharging of a battery is controlled according to the reference signal.

While the foregoing description and drawings represent embodiments of the present invention, it will be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

What is claimed is:

1. A circuit for generating a reference signal, said circuit comprising:
a first resistor string and a second resistor string substantially identical to said first resistor;
a trim controller coupled to said first resistor string and operable for selectively passing a terminal voltage at a terminal in said first resistor string;
an amplifier coupled to said trim controller and operable for comparing said terminal voltage to a second voltage to generate said reference signal; and
a resistor controller coupled to said first resistor string and said second resistor string and operable for selectively shorting out a resistor in said first resistor string and a corresponding resistor in said second resistor string.

2. The circuit of claim 1, further comprising:
a terminal selector coupled to said second resistor string and operable for selectively providing a terminal voltage at a terminal in said second resistor string as a second reference signal.

3. The circuit of claim 1, wherein said first resistor string and said second resistor string are coupled in parallel.

4. The circuit of claim 1, wherein said trim controller comprises a multiplexer for selectively passing said terminal voltage at said terminal in said first resistor string.

5. The circuit of claim 1, wherein said reference signal indicates an over-voltage threshold for a battery.

6. The circuit of claim 1, wherein said reference signal indicates an under-voltage threshold for a battery.

7. The circuit of claim 1, wherein said reference signal indicates an over-current threshold for a battery.

8. A battery management circuit comprising:
circuitry coupled to a battery and operable for controlling charging and discharging of said battery according to a reference signal;
a reference circuit coupled to said circuitry and operable for generating said reference signal, said reference circuit comprising:
a first resistor string and a second resistor string substantially identical to said first resistor;
a trim circuit coupled to said first resistor string and operable for generating said reference signal according to a terminal voltage at a terminal in said first resistor string; and
a resistor controller coupled to said first resistor string and said second resistor string and operable for selectively shorting out a resistor in said first resistor string and a corresponding resistor in said second resistor string.

9. The battery management circuit of claim 8, wherein said first resistor string and said second resistor string are coupled in parallel.

10. The battery management circuit of claim 8, wherein said trim circuit comprises a trim controller coupled to said first resistor string and operable for selectively passing a terminal voltage at a terminal in said first resistor string.

11. The battery management circuit of claim 10, wherein said trim circuit further comprises an amplifier coupled to said trim controller and operable for comparing said terminal voltage to a second voltage to generate said reference signal.

12. The battery management circuit of claim 8, wherein said reference circuit further comprises a terminal selector coupled to said second resistor string and operable for selectively providing a terminal voltage at a terminal in said second resistor string as a second reference signal.

13. The battery management circuit of claim 8, wherein said circuitry terminates battery charging if a battery voltage of said battery is greater than said reference signal.

14. The battery management circuit of claim 8, wherein said circuitry terminates battery discharging if a battery voltage of said battery is less then said reference signal.

15. The battery management circuit of claim 8, wherein said reference signal indicates an over-voltage threshold for said battery.

16. The battery management circuit of claim 8, wherein said reference signal indicates an under-voltage threshold for said battery.

17. A method comprising:
selectively passing a terminal voltage at a terminal in a first resistor string;
comparing said terminal voltage to a second voltage to generate a reference signal; and
selectively shorting out a resistor in said first resistor string and a corresponding resistor in a second resistor string which is substantially identical to said first resistor string.

18. The method of claim 17, further comprising:
selectively providing a terminal voltage at a terminal in said second resistor string as a second reference voltage.

19. The method of claim 17, further comprising:
controlling charging of a battery according to said reference signal.

20. The method of claim 17, further comprising:
controlling discharging of a battery according to said reference signal.
